(19) United States
(12) Patent Application Publication
(10) Pub. No.: US 2023/0197472 A1
(43) Pub. Date: Jun. 22, 2023

(54) SYSTEMS AND METHODS FOR CONTROLLING MOISTURE IN SEMICONDUCTOR PROCESSING SYSTEMS

(71) Applicant: ASM IP Holding, B.V., Almere (NL)

(72) Inventors: Joseph Kraus, Brandon, FL (US); Mario Gonzalez, Phoenix, AZ (US); Mandar Deshpande, Phoenix, AZ (US)

(21) Appl. No.: 18/065,869

(22) Filed: Dec. 14, 2022

Related U.S. Application Data
(60) Provisional application No. 63/290,173, filed on Dec. 16, 2021.

(51) Int. Cl. H01L 21/67; C23C 16/44

(52) U.S. Cl. CPC H01L 21/67063; C23C 16/4408; H01L 21/67167; H01L 21/67201

(57) ABSTRACT

A semiconductor processing system includes a front-end module connected to a load lock, a process module coupled to the front-end module by the load lock, a purge/vent fluid inlet conduit connected to the load lock, a heater element coupled to the load lock by the purge/vent fluid inlet conduit, and a controller. The controller is operably connected to the heater element and responsive to instructions recorded on a memory to transfer a substrate carrying substrate moisture from the front-end module into the load lock, heat a purge/vent fluid using the heater element, flow the heated purge/vent fluid into the load lock using the purge/vent fluid inlet conduit, remove the moisture from the load lock using the heated purge/vent fluid, and transfer the substrate from the load lock to the process module for processing using the process module. Moisture control methods and heated purge/vent fluid arrangements are also described.

### CROSS-REFERENCE TO RELATED APPLICATIONS

This application claims priority to and the benefits of U.S. Provisional Application No. 63/290,173, filed on Dec. 16, 2021, the contents of which are incorporated herein by reference in its entirety.

### FIELD OF INVENTION

The present disclosure generally relates to fabricating semiconductor devices. More particularly, the present disclosure relates to controlling moisture in semiconductor processing systems employed to fabricate semiconductor devices.

### BACKGROUND OF THE DISCLOSURE

Semiconductor devices are commonly fabricated by processing substrates in semiconductor processing systems adapted for various processing operations such as patterning, etching, and material layer deposition. Material layer deposition is generally accomplished by supporting a substrate, e.g., a silicon wafer, in a film deposition system. The substrate is typically heated to a desired deposition temperature within an environmentally controlled chamber and a material layer precursor flowed through the chamber and across the substrate. As the material layer precursor flows through the chamber and across the substrate a chemical reactor occurs, causing a material layer to form on the substrate. Material layer deposition may be accomplished using a chemical vapor deposition (CVD) technique such epitaxy, an atomic layer deposition (ALD) technique, a plasma-enhanced CVD techniques, or a plasma-enhanced ALD technique.

In some semiconductor processing systems, moisture may infiltrate interior spaces within the semiconductor processing system, potentially limiting reliability of the semiconductor processing system and/or influencing properties of material layers deposited using the semiconductor processing system. For example, water vapor may infiltrate the semiconductor processing system from the environment external to the semiconductor processing system, increasing humidity in the semiconductor processing system. Moisture may also be introduced into the semiconductor processing system during substrate transfer, such as on the substrate surface and/or by gas flows that may occur during transfers. The moisture vapor may thereafter condense on various surfaces and/or structures within the semiconductor processing system, potentially causing the surfaces and/or structure to corrode as well as influencing properties of the material layers deposited onto substrates in the semiconductor processing system. And residual material layer precursor and/or reaction products may condense within some semiconductor processing systems, posing further corrosion and/or material property risks.

Various countermeasures exist to limit moisture in semiconductor processing systems. For example, some semiconductors are maintained at internal elevated pressure with respect to the ambient environment outside the semiconductor processing system. The elevated internal pressure generally discourages infiltration of air from the ambient environment into the semiconductor processing system, limiting the tendency of water vapor resident in the ambient environment to enter the semiconductor processing system. Conditioned purge flows may be provided to some semiconductor processing systems. The conditioned purge flows typically displace air from within the interior of the semiconductor processing system, driving vapor out of the interior of the semiconductor processing system. And some semiconductor processing systems employ heaters to heat various structures and/or substrates in the semiconductor processing system to mobilize liquids resident within the interior of the semiconductor processing system.

Such systems and methods have generally been satisfactory for their intended purpose. However, there remains a need for improved semiconductor processing systems, moisture control methods, and heated purge/vent fluid arrangements for semiconductor processing systems. The present disclosure provides a solution to this need.

### SUMMARY OF THE DISCLOSURE

A semiconductor processing system is provided. The semiconductor processing system includes a front-end module connected to a load lock, a process module coupled to the front-end module by the load lock, a purge/vent fluid inlet conduit connected to the load lock, a heater element coupled to the load lock by the purge/vent fluid inlet conduit, and a controller. The controller is operably connected to the heater element and responsive to instructions recorded on a non-transitory machine-readable medium to transfer a substrate carrying substrate moisture from the front-end module into the load lock, heat a purge/vent fluid using the heater element, flow the heated purge/vent fluid into the load lock using the purge/vent fluid inlet conduit, remove the substrate moisture from the load lock using the heated purge/vent fluid, and transfer the substrate from the load lock to the process module for processing using the process module.

In addition to one or more of the features described above, or as an alternative, further examples of the semiconductor processing system may include a purge/vent fluid inlet valve arranged along the purge/vent fluid inlet conduit.

In addition to one or more of the features described above, or as an alternative, further examples of the semiconductor processing system may include a purge/vent fluid inlet mass flow controller arranged along the purge/vent fluid inlet conduit and operatively associated with the controller.

In addition to one or more of the features described above, or as an alternative, further examples of the semiconductor processing system may include a purge/vent fluid source fluidly coupled the purge/vent fluid inlet conduit and therethrough to an interior of the load lock.

In addition to one or more of the features described above, or as an alternative, further examples of the semiconductor processing system may include an evacuation conduit connected to the load lock, an evacuation pump connected to the evacuation conduit and fluidly coupled therethrough to the interior of the load lock, and an evacuation mass flow controller (MFC) arranged along the evacuation conduit and operably associated with the controller.

In addition to one or more of the features described above, or as an alternative, further examples of the semiconductor processing system may include a hygrometer fluidly coupled to the load lock and disposed in communication with the controller. The instructions recorded on the controller in such examples may further cause the controller to acquire a dew point measurement from an interior of the load lock using the hygrometer, compare the dew point measurement to a predetermined dew point value using the controller, increase mass flow of the heated purge/vent fluid admitted to the load lock when the dew point measurement is greater than the predetermined dew point value, and decrease mass flow of the heated purge/vent fluid admitted to the load lock when the dew point measurement is less than the predetermined dew point value.

In addition to one or more of the features described above, or as an alternative, further examples of the semiconductor processing system may include a front-end gate valve coupling the front-end module to the load lock, a back-end gate valve coupling the load lock to the process module, and an evacuation pump coupled to the interior of the load lock. The instructions recorded on the memory in such examples may further cause the controller to remove evaporated moisture from the interior of the load lock through at least one of the front-end gate valve, the back-end gate valve, and the evacuation.

A moisture control method is provided. The method includes, at semiconductor processing system as described above, transferring a substrate carrying substrate moisture from the front-end module into the load lock and heating a purge/vent fluid using the heater element. The heated purge/vent fluid is flowed into the load lock using the purge/vent fluid inlet conduit, the substrate moisture is removed from the load lock using the heated purge/vent fluid, and the substrate is thereafter transferred from the load lock to the process module for processing using the process module.

In addition to one or more of the features described above, or as an alternative, further examples of the method may include that the heated purge/vent fluid comprises (a) cleanroom air; (b) clean, dry air; (c) nitrogen; or (d) high purity nitrogen; wherein the substrate moisture comprises water.

In addition to one or more of the features described above, or as an alternative, further examples may include a cartridge heater seated in a wall of the load lock or an external heater, and that the method further includes heating the wall of the load lock using the cartridge heater or external heater.

In addition to one or more of the features described above, or as an alternative, further examples may include a purge/vent fluid inlet valve arranged along the purge/vent fluid inlet conduit and operatively associated with the controller, and that the method further includes closing the purge/vent fluid inlet valve prior to transferring the substrate to the process module.

In addition to one or more of the features described above, or as an alternative, further examples may include that the semiconductor processing system further includes a purge/vent mass flow controller (MFC) arranged along the purge/vent fluid inlet conduit and operatively associated with the controller, and that flowing the heated purge/vent fluid to the load lock includes throttling mass flow of the purge/vent fluid using the purge/vent MFC.

In addition to one or more of the features described above, or as an alternative, further examples may include that the semiconductor processing system further includes a front-end gate valve coupling the front-end module to the load lock, and that the removing the substrate moisture includes flowing the heated purge/vent fluid and evaporated moisture through the front-end gate valve.

In addition to one or more of the features described above, or as an alternative, further examples may include that the semiconductor processing system further includes a back-end gate valve coupling the load lock to the process module, and that removing the substrate moisture includes flowing the heated purge/vent fluid and evaporated moisture through the back-end gate valve.

In addition to one or more of the features described above, or as an alternative, further examples may include that surface moisture is located on an interior surface and/or structure within the load lock, and that the method further includes removing the surface moisture from an interior surface or structure within the load lock using the heated purge/vent fluid.

In addition to one or more of the features described above, or as an alternative, further examples may include that the semiconductor processing system includes an evacuation pump fluidly coupled to the load lock, and that removing the substrate moisture includes evacuating the heated purge/vent gas and evaporated moisture from the load lock using the evacuation pump.

In addition to one or more of the features described above, or as an alternative, further examples of the method may include the substrate moisture consists of condensed water resident on a surface of the substrate.

In addition to one or more of the features described above, or as an alternative, further examples of the method may include that the substrate is an unprocessed substrate, and that the method further includes flowing residual precursor and/or etchant/reaction products from the process module into the load lock, condensing the residual precursor and/or etchant/reaction products within the load lock, vaporizing the condensed residual precursor and/or etchant/reaction products using the heated purge/vent fluid, and removing the vaporized residual precursor and/or etchant/reaction products from the load lock using the heated purge/vent fluid.

In addition to one or more of the features described above, or as an alternative, further examples may include that the semiconductor processing system further includes a hygrometer fluidly coupled to the load lock chamber and disposed in communication with the controller, and that the method further includes the method further acquiring a dew point measurement from an interior of the load lock using the hygrometer; comparing the dew point measurement to a predetermined dew point value using the controller, increasing mass flow of the heated purge/vent fluid admitted to the load lock when the dew point measurement is greater than the predetermined dew point value, and decreasing mass flow of the heated purge/vent fluid admitted to the load lock when the dew point measurement is less than the predetermined dew point value.

A heated purge/vent fluid arrangement for a semiconductor processing system is provided. The heated purge/vent fluid arrangement includes a heater element and a computer program product. The heater element is configured to be connected to a purge/vent fluid inlet conduit and thermally coupled therethrough to a load lock of the semiconductor processing system. The computer program product includes a non-transitory machine-readable medium having a plurality of program modules recorded on the medium containing instructions that, when read by a processor, cause the processor to transfer a substrate carrying substrate moisture from a front-end module of the semiconductor processing system into the load lock, heat a purge/vent fluid using the heater element, flow the heated purge/vent fluid into the load lock using the purge/vent fluid inlet conduit, remove the substrate moisture from the load lock using the heated purge/vent fluid, and transfer the substrate from the load lock to a process module of the semiconductor processing system for processing using the process module.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain examples, which are intended to illustrate and not to limit the present disclosure.

FIG. 1 is a schematic view of a semiconductor processing system, showing a load lock with a heater element coupling a front-end module of the semiconductor processing system to a back-end module of the semiconductor processing system;

FIG. 2 is a schematic view of the load lock and the heater element of FIG. 1 according to an example, showing the heater element heating a purge gas prior to the purge gas being admitted into the interior of the load lock;

FIGS. 3 and 4 are schematic views of the load lock and the heater element according to the example illustrated in FIG. 2, showing a heated purge gas admitted to the lock removing moisture from an interior surface and/or structure within the load lock prior to transfer of a substrate into the load lock from the front-end module of the semiconductor processing system;

FIGS. 5 and 6 are schematic views of the load lock and the heater element according to the example illustrated in FIG. 2, showing a heated purge gas admitted to the lock removing moisture from a surface of substrate supported within the load prior to transfer of the substrate into the back-end module of the semiconductor processing system;

FIG. 7 is a schematic view of the load lock and the heater element of FIG. 1 according to another example, showing the heater element heating a vent gas prior to the vent being admitted into the interior of the load lock;

FIGS. 8 and 9 are schematic views of the load lock and the heater element according to the example illustrated in FIG. 7, showing a heated purge gas admitted to the lock removing moisture from an interior surface and/or structure within the load lock prior to transfer of a substrate into the load lock from the front-end module of the semiconductor processing system;

FIGS. 10 and 11 are schematic views of the load lock and the heater element according to the example illustrated in FIG. 2, showing a heated purge gas admitted to the lock removing moisture from a surface of substrate supported within the load prior to transfer of the substrate into the back-end module of the semiconductor processing system; and

FIGS. 12-14 are a block diagram of a method of controlling moisture in a semiconductor processing system, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated examples of the present disclosure.

### DETAILED DESCRIPTION OF EXEMPLARY EMBODIMENTS

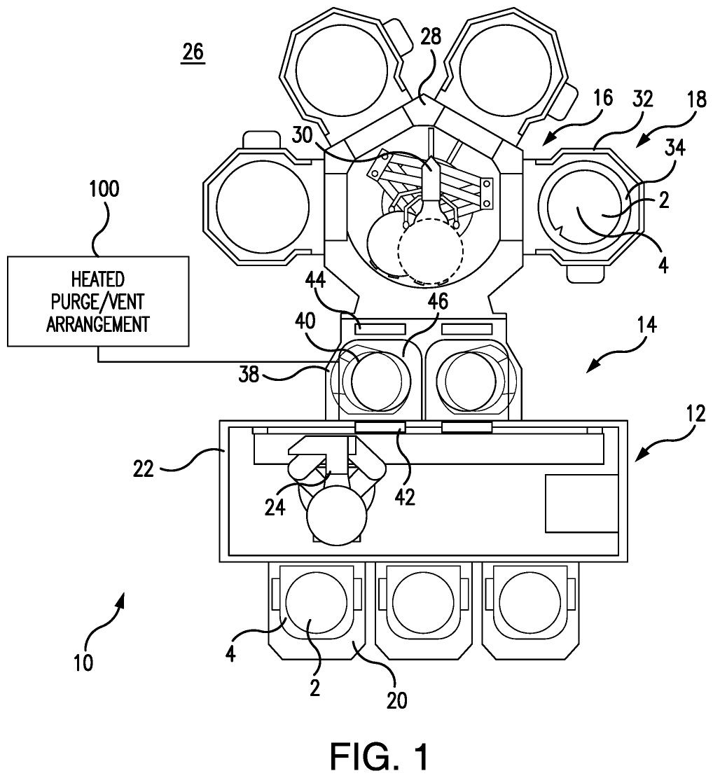

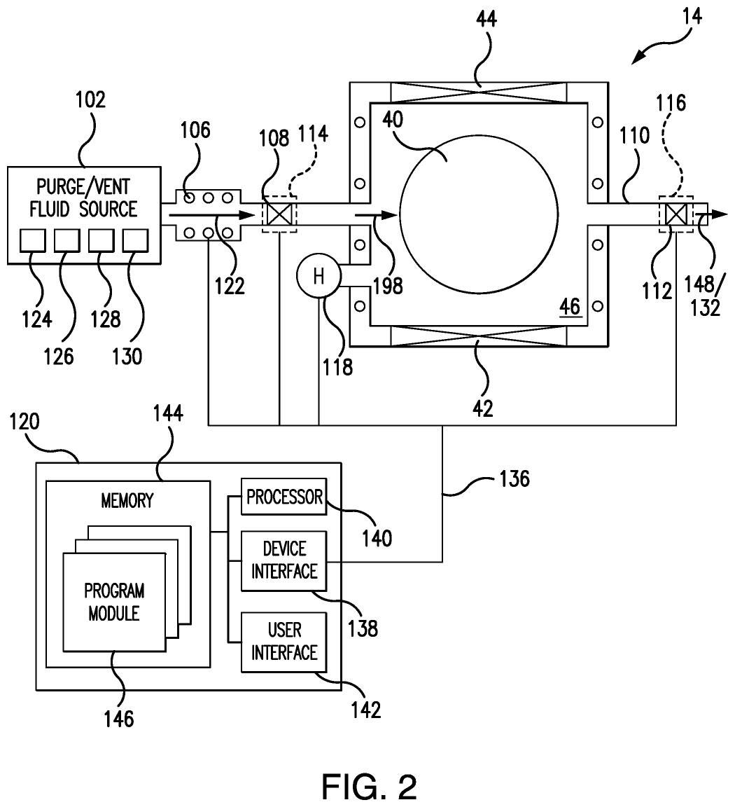

Reference will now be made to the drawings wherein like reference numerals identify similar structural features or aspects of the subject disclosure. For purposes of explanation and illustration, and not limitation, a partial view of an example of a semiconductor processing system including a heated purge/vent fluid arrangement in accordance with the present disclosure is shown in FIG. 1 and is designated generally by reference character 10. Other examples of semiconductor processing systems, methods of controlling moisture from within semiconductor processing systems, and heated purge/vent fluid arrangements in accordance with the present disclosure, or aspects thereof, are provided in FIGS. 2-14, as will be described. The systems and methods of the present disclosure may be used to control moisture in semiconductor processing systems employed to deposit material layers onto substrates, such as in semiconductor processing systems employing chemical vapor deposition (CVD) and an atomic layer deposition (ALD) techniques to deposit material layers onto substrates, though the present disclosure is not limited to any particular deposition technique or to semiconductor processing systems employed for material layer deposition in general.

Referring to FIG. 1, the semiconductor processing system 10 is shown. The semiconductor processing system 10 generally includes a front-end module 12, a load lock 14, a back-end module 16, and a process module 18. The front-end module 12 includes a load port 20, a front-end enclosure 22, and a front-end substrate transfer robot 24. The load port 20 is connected to the front-end enclosure 22 and configured to seat thereon a pod, e.g., a front-opening unified pod (FOUP), supporting one or more substrate 2. The front-end enclosure 22 is connected to the load lock 14, houses the front-end substrate transfer robot 24, and is configured to maintain an internal enclosure pressure that is substantially equivalent (e.g., slightly higher) than that of the external environment 26 outside the semiconductor processing system 10. The front-end substrate transfer robot 24 is supported for movement within the interior of the front-end enclosure 22 and is configured to transfer substrates, e.g., the substrate 2, between the load port 20 and the load lock 14. In certain examples, the substrate 2 may include a wafer, such as 300-millimeter wafer. In accordance with certain examples, the substrate 2 may include a blanket substrate. It is also contemplated that the substrate 2 may include a patterned substrate.

The back-end module 16 includes a back-end chamber 28 and a back-end substrate transfer robot 30. The back-end chamber 28 is connected to the load lock 14 and is coupled therethrough to the front-end module 12. The back-end chamber 28 is also connected to the process module 18 and couples the process module 18 to the load lock 14, and therethrough to the front-end module 12. The back-end substrate transfer robot 30 is supported for movement within the interior of the back-end chamber 28 and is configured to transfer substrates, e.g., the substrate 2, between the load lock 14 and the process module 18. In certain examples, the back-end chamber 28 may be purged, i.e., maintain pressure therein substantially equivalent to pressure within the external environment 26. In accordance with certain examples, the back-end chamber 28 may be evacuated, i.e., maintain pressure below that of the external environment 26. As shown in FIG. 1, four (4) process modules are connected to the back-end chamber 28 and coupled therethrough to the load lock 14. As will be appreciated by those of skill in the art in view of the present disclosure, the semiconductor processing system 10 may have fewer or additional process modules and remain within the scope of the present disclosure.

The process module 18 includes a process chamber 32, a substrate support 34, and a process module gate valve 36. The process chamber 32 is connected to the back-end chamber 28 and houses the substrate support 34. The substrate support 34 is arranged within the process chamber 32 and is configured to support thereon a substrate, e.g., the substrate 2, during deposition of a material layer 4 onto the substrate 2. The process module gate valve 36 is arranged between the process chamber 32 and the back-end chamber 28, couples the process module 18 to the back-end module 16, and is configured to provide selective communication between the process module 18 and the back-end module 16 for transfer of substrates (e.g., the substrate 2) between the back-end module 16 and the process module 18. In certain examples, the process module 18 may be configured to deposit epitaxial material layers onto substrates using a CVD technique. In accordance with certain examples, the process module 18 may be configured to deposit material layers onto substrates using an ALD technique. It is also contemplated that the process module 18 may be a deposition process module, and that the semiconductor processing system 10 may include a preclean process module.

The load lock 14 includes a load lock housing 38, a chill plate/substrate rack 40, a front-end gate valve 42, and a back-end gate valve 44. The load lock housing 38 is connected to the front-end enclosure 22 and the back-end chamber 28. The chill plate/substrate rack 40 is arranged within an interior 46 of the load lock housing 38 and is configured to support thereon one or more substrate, e.g., the substrate 2, during transfer of the substrate between the front-end module 12 and the back-end module 16. The front-end gate valve 42 is arranged between the front-end enclosure 22 and the load lock housing 38, couples the load lock 14 to the front-end module 12, and is configured to provide selective communication between the front-end module 12 and the load lock 14 for transfer of substrates between the front-end module 12 and the load lock 14. The back-end gate valve 44 is arranged between the load lock housing 38 and the back-end chamber 28, couples the load lock 14 to the back-end module 16, and is configured to provide selective communication between the load lock 14 and the back-end module 16 for transfer of substrates between the load lock 14 and the back-end module 16.

During operation, unprocessed substrates (e.g., the substrate 2) are transferred from the front-end module 12 to the process module 18 through the load lock 14 and the back-end module 16. Once transferred into the process module 18, the substrate undergo processing—during which a material layer (e.g., the material layer 4) is deposited onto the substrate. The processed substrate (i.e., the substrate and the material layer) are thereafter transferred from the process module 18 to the front-end module 12 through the back-end module 16 and the load lock 14. As has been explained, during operation of some semiconductor processing systems, moisture may infiltrate interior spaces of the semiconductor processing system employed for the deposition operation. For example, water vapor from the external environment may infiltrate the interior of the load lock certain semiconductor processing system, such as through purge flows provided to the load and/or through the front-end gate valve connected to the load lock during transfer of substrates into the load lock. Water may also be carried into the load lock by substrates during transfer between the front-end module and the load lock, potentially increasing humidity within the load lock as well as the associated risk that water may condense onto interior surfaces and structures within the load lock. And residual precursor and/or reaction product vapors may infiltrate the interior of the load lock through the back-end gate valve coupling the load lock to the back-end module, the residual precursor and/or reaction products potentially condensing onto interior surfaces and/or structures within the load lock. Since such moisture can potentially lead to corrosion within the load lock 14 and/or influence properties of material layers deposited within the process module 18, the semiconductor processing system 10 incudes a heated purge/vent fluid arrangement 100. The heated purge/vent fluid arrangement 100 is configured to heat a purge/vent fluid, e.g., a purge/vent fluid 122 (shown in FIG. 2), prior to admission of the purge/vent fluid 122 into the load lock 14.

With reference to FIG. 2, the load lock 14 and the heated purge/vent fluid arrangement 100 are shown. The heated purge/vent fluid arrangement 100 includes a purge/vent fluid source 102, a purge/vent fluid inlet conduit 104, and a heater element 106. The heated purge/vent fluid arrangement 100 also includes a purge/vent fluid inlet valve 108, a purge/vent fluid outlet conduit 110, and a purge/vent fluid outlet valve 112. The heated purge/vent fluid arrangement 100 further include a purge/vent fluid inlet mass flow controller (MFC) 114, a purge/vent fluid outlet MFC 116, a hygrometer 118, and a controller 120. In certain examples, and, in certain examples, may be heated purge/vent fluid arrangement 100 may be a kit configured for installation on a legacy semiconductor processing system. As will be appreciated by those of skill in the art in view of the present disclosure, the heated purge/vent fluid arrangement 100 may include fewer or additional elements than shown in FIG. 2 and remain within the scope of the present disclosure.

The purge/vent fluid source 102 is connected to the load lock 14 and is configured to provide a flow of a purge/vent fluid 122 to the load lock 14. In certain examples, the purge/vent fluid source 102 may include an air intake 124, which may be arranged within the external environment 26 outside the semiconductor processing system 10 (shown in FIG. 1). In such examples the purge/vent fluid 122 may include cleanroom air. In accordance with certain examples, the purge/vent fluid source 102 may include a clean, dry air (CDA) system 126. In such examples the purge/vent fluid 122 may include CDA, such as from a fabrication facility CDA system. In further examples, the purge/vent fluid source 102 may include a nitrogen source 128, the purge/vent fluid 122 in such examples include nitrogen gas. It is also contemplated that, in accordance with certain example, that the purge/vent fluid source 102 may include a high purity nitrogen (HPN) source 130. In such examples the purge/vent fluid 122 may include HPN gas, such as from a fabrication facility HPN system.

The purge/vent fluid inlet conduit 104 connects the purge/vent fluid source 102 to the load lock 14 and is configured to flow the purge/vent fluid 122 to the load lock 14. In this respect it is contemplated that the purge/vent fluid inlet conduit 104 fluidly couple the purge/vent fluid source 102 to the heater element 106. In further respect, it is also contemplated that the purge/vent fluid inlet conduit 104 fluidly couple the purge/vent fluid source 102 to the purge/vent fluid inlet valve 108 for selective fluid coupling therethrough of the purge/vent fluid source 102 to the interior 46 of the load lock 14.

The heater element 106 is arranged along the purge/vent fluid inlet conduit 104 and is configured to heat the purge/vent fluid 122 to provide a heated purge/vent fluid 148 for admission to the interior 46 of the load lock 14. In certain examples the heater element 106 may be operatively associated with the controller 120, and may include an electric heating element to heat the purge/vent fluid 122. In accordance with certain examples, the heater element 106 may be at least partially arranged within an interior of the purge/vent fluid inlet conduit 104, the heater element 106 fluidly coupled in such examples to the purge/vent fluid inlet valve 108. It is also contemplated that, in accordance with certain example, that the heater element 106 may be connected to an exterior of the purge/vent fluid inlet conduit 104, the heater element 106 thermally coupled to the load lock 14 is such examples by a wall of the purge/vent fluid inlet conduit 104 to heat the purge/vent fluid 122 prior to admission to the interior 46 of the load lock 14. For example, the heater element 106 may be conformally fixed to an exterior surface of the purge/vent fluid inlet conduit 104.

The purge/vent fluid inlet valve 108 is arranged along the purge/vent fluid inlet conduit 104 and is configured to provide selective fluid communication with the interior 46 of the load lock 14. In this respect it is contemplated that the purge/vent fluid inlet valve 108 have an open position, wherein the purge/vent fluid inlet valve 108 fluidly couples the purge/vent fluid source 102 to the interior 46 of the load lock 14, and a closed position, wherein the purge/vent fluid inlet valve 108 fluidly separates the purge/vent fluid source 102 from the interior 46 of the load lock 14. The purge/vent fluid inlet valve 108 may be operatively associated with the controller 120, the controller 120 in such examples configured to move the purge/vent fluid inlet valve 108 between the open position and the closed position to provide selective fluid communication between the purge/vent fluid source 102 and the interior 46 of the load lock 14.

The purge/vent fluid outlet conduit 110 fluidly connects the load lock 14 to the external environment 26. It is contemplated that the purge/vent fluid outlet conduit 110 fluidly couples the interior 46 of the load lock 14 to the purge/vent fluid outlet valve 112 for selective fluid coupling therethrough of the interior 46 of the load lock 14 to the external environment 26. In this respect the purge/vent fluid outlet conduit 110 is configured to flow the heated purge/vent fluid 148 from the interior 46 of the load lock 14 to the external environment 26 (shown in FIG. 1). In further respect, it is further contemplated that the purge/vent fluid outlet conduit 110 be configured to flow the heated purge/vent fluid 148 and evaporated moisture 132 to the external environment 26 outside of the load lock 14.

The purge/vent fluid outlet valve 112 is arranged along the purge/vent fluid outlet conduit 110 and is configured to provide selective fluid communication between the interior 46 of the load lock 14 external environment 26. In this respect it is contemplated that the purge/vent fluid outlet valve 112 have an open position, wherein the purge/vent fluid outlet valve 112 fluidly couples the interior 46 of the load lock 14 to the external environment 26, and a closed position, wherein the purge/vent fluid outlet valve 112 fluidly separates the interior 46 of the load lock 14 from the external environment 26. The purge/vent fluid outlet valve 112 may be operatively associated with the controller 120, the controller 120 in such examples configured to move the purge/vent fluid outlet valve 112 between the closed position and the open position to provide selective fluid communication between the interior 46 of the load lock 14 and the external environment 26 for flowing the purge/vent fluid 122 and evaporated moisture 132 from the interior 46 of the load lock 14.

The hygrometer 118 is connected to the load lock 14 by a sampling conduit, is fluidly coupled to the interior 46 of the load lock 14, and is configured to acquire a dew point measurement 134 from the atmosphere within the interior 46 of the load lock 14. It is contemplated that the hygrometer 118 be disposed in communication with the controller 120, for example by a wired or wireless link 136, to provide a signal including the dew point measurement 134 to the controller 120. Examples of suitable hygrometers MicroView On-Line Hygrometers, available from Moisture Control & Measurement Ltd of West Yorkshire, United Kingdom.

In certain examples, the purge/vent fluid inlet valve 108 may be included in a purge/vent fluid inlet mass flow controller (MFC) 114. In such examples the purge/vent fluid inlet MFC 114 may be configured to throttle mass flow of the purge/vent fluid 122 flowing through the purge/vent fluid inlet conduit 104, for example using the purge/vent fluid inlet valve 108. The purge/vent fluid inlet MFC 114 may be operatively associated with the controller 120. The controller 120 in turn may be configured to throttle mass flow of the purge/vent fluid 122 flowing through the purge/vent fluid inlet conduit 104 using the purge/vent fluid inlet MFC 114. As will be appreciated by those of skill in the art in view of the present disclosure, throttling flow of the purge/vent fluid 122 flowing into the interior 46 of the load lock 14 for control of the rate of moisture removal within the load lock 14 using the heated purge/vent fluid 148. Throttling may be accomplished using a dew point measurement acquired from the interior 46 of the load lock 14 using the hygrometer 118, mass flow of the heated purge/vent fluid 148 into the load lock 14 and/or mass flow of the heated purge/vent fluid 148 and the evaporated moisture 132 increased or decreased based on the acquired dew point measurement.

In certain examples, the purge/vent fluid outlet valve 112 may be included in a purge/vent fluid outlet MFC 116. The purge/vent fluid outlet MFC 116 may be similar to the purge/vent fluid inlet MFC 114 and additionally configured to throttle mass flow of the purge/vent fluid 122 flowing through the purge/vent fluid outlet conduit 110, for example using the heated purge/vent fluid 148 and the evaporated moisture 132 flowing through the purge/vent fluid outlet valve 112. It is contemplated that the purge/vent fluid outlet MFC 116 may be operatively associated with the controller 120, and that the controller 120 in turn be configured to throttle mass flow of the heated purge/vent fluid 148 and evaporated moisture 132 flowing through the purge/vent fluid outlet conduit 110 using the purge/vent fluid outlet MFC 116. As will be appreciated by those of skill in the art in view of the present disclosure, throttling flow of the heated purge/vent fluid 148 and evaporated moisture 132 allows for control of residency time of heated purge/vent fluid 148, and the associated evaporation of moisture from with the interior 46 of the load lock 14, corresponding to the residency time within the interior 46 of the load lock 14.

The controller 120 includes a device interface 138, a processor 140, a user interface 142, and a memory 144. The device interface 138 provides communication between the processor 140 and the heater element 106, for example over the wired or wireless link 136, the controller 120 thereby operatively associated with the heater element 106. The processor 140 is further operatively connected to the user interface 142 to receive user input and/or provide user output, respectively, and is disposed in communication with the memory 144. The memory 144 includes a non-transitory machine-readable medium having a plurality of program modules 146 recorded on the medium that, when read by the processor 140, cause the processor 140 to execute certain operations. Among the operations are operations of a moisture control method 300, as will be described. Although a particular arrangement of the controller 120 is shown and described herein it is to be understood and appreciated that the controller 120 may have other architectures, e.g., a distributed computing architecture, and remain within the scope of the present disclosure.

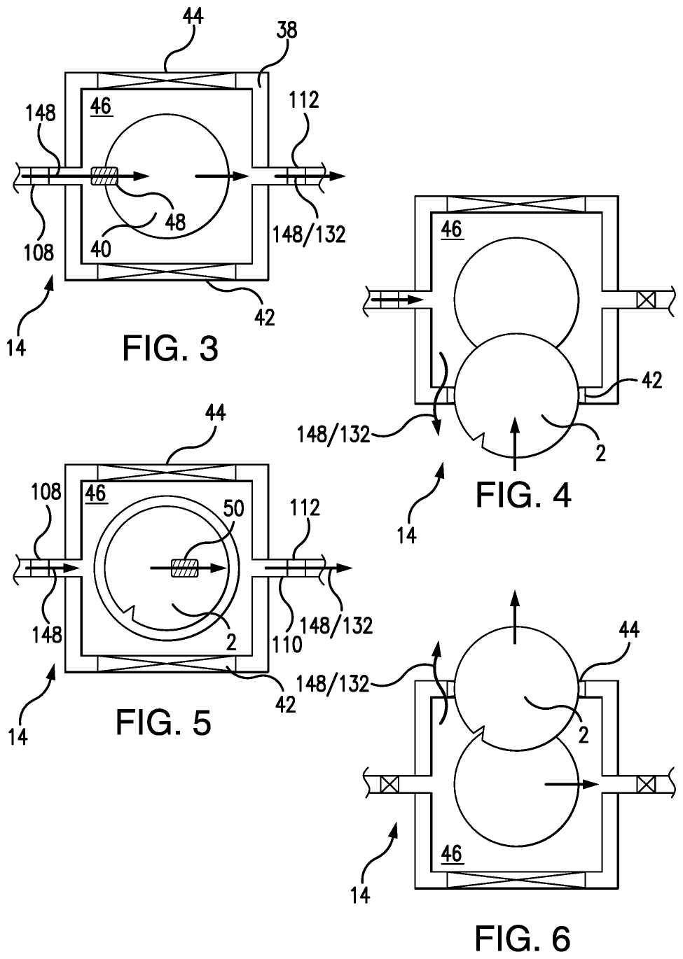

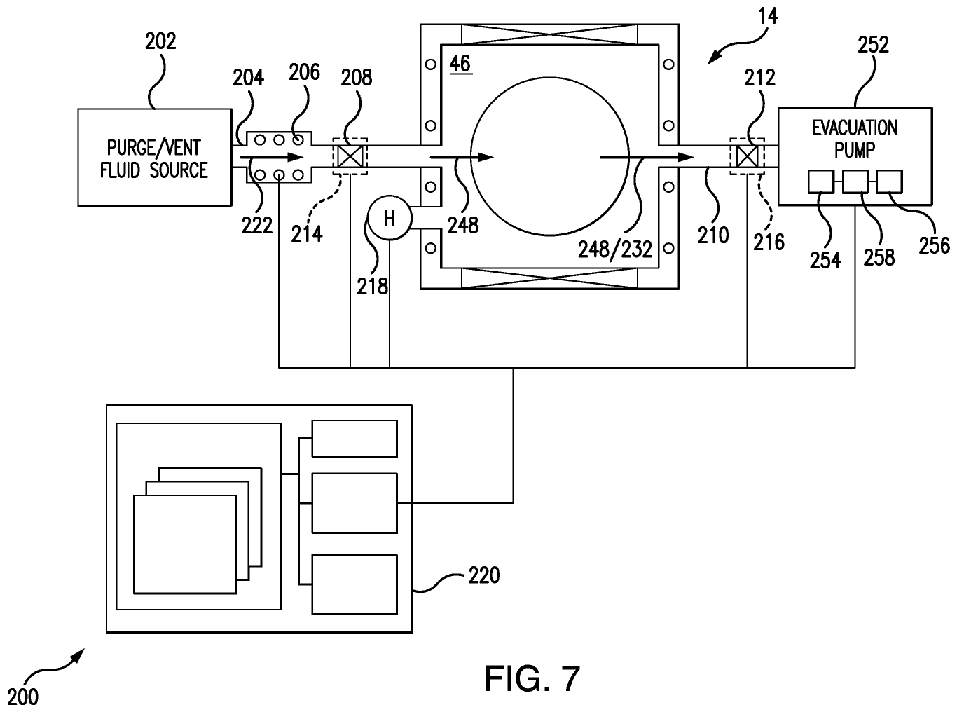

With reference to FIGS. 3-6, moisture removal from within the load lock 14 during substrate transfer from the front-end module 12 (shown in FIG. 1) to the back-end module 16 (shown in FIG. 1) are shown in an example where a purged atmosphere of substantially ambient pressure is maintained within the back-end chamber 28 (shown in FIG. 1). As shown in FIGS. 3 and 4, it is contemplated that surface moisture 48 (e.g., one or more of condensed water, a condensed residual precursor, a condensed residual etchant, and/or a condensed residual reaction product) resident on an interior surface and/or structure within the load lock housing 38 (e.g., on the chill plate/substrate rack 40) be removed using the heated purge/vent fluid 148. As shown in FIGS. 5 and 6, it is also contemplated that substrate moisture 50 (e.g., condensed water) carried by unprocessed substrates, e.g., the substrate 2 (shown in FIG. 1), also be removed using the heated purge/vent fluid 148. As will be appreciated by those of skill in the art in view of the present disclosure, removal of surface moisture and/or substrate moisture limits (or eliminates) risk that such moisture cause corrosion in the load lock 14 and/or the back-end module 16. As will also be appreciated by those of skill in the art in view of the present disclosure, removal of surface moisture and/or substrate moisture also limits (or eliminates) risk that such moisture influence processing of the substrate, for example, by altering properties of material layers deposited onto substrates processed by the semiconductor processing system 10 (shown in FIG. 1). Although shown in the context of moisture removal during transfer of an unprocessed substrate, it is to be understood and appreciated that the heated purge/vent arrangement may also be employed to remove moisture during the transfer of processed substrates.

Referring to FIG. 3, the surface moisture 48 may be removed from within the interior 46 of the load lock 14 by (a) fluidly separating the interior 46 of the load lock 14 from the front-end module 12 (shown in FIG. 1) and the back-end module 16 (shown in FIG. 1), (b) heating the purge/vent fluid 122 (shown in FIG. 2), and (c) providing heated purge/vent fluid 148 to the interior 46 of the load lock 14. Therein (d) the heated purge/vent fluid 148 evaporate the surface moisture 48, and (e) the heated purge/vent fluid 148 and evaporated moisture 132 is thereafter removed from the load lock 14. Fluid separation of the interior 46 of the load lock 14 from the front-end module 12 and the back-end module 16 be accomplished by closing the front-end gate valve 42 and the back-end gate valve 44, respectively.

Heating of the purge/vent fluid 122 is accomplished outside of the load lock 14 as the purge/vent fluid 122 transverses the heater element 106. Provision of the heated purge/vent fluid 148 is accomplished opening the purge/vent fluid inlet valve 108. Evaporation of the surface moisture 48 is accomplished by heating the surface moisture 48 using the heated purge/vent fluid 148. Removal of the heated purge/vent fluid 148 and the evaporated moisture 132 is accomplished by opening the purge/vent fluid outlet valve 112 to the open position. Advantageously, as the heated purge/vent fluid 148 directly heats the surface moisture 48, removal of the surface moisture 48 is relatively rapid in comparison to methods requiring communication of heat through the bulk material forming the load lock housing 38, for example, using a cartridge heater embedded within the load lock housing 38 and/or an external heat lamp.

In certain examples, flow of the heated purge/vent fluid 148 may be throttled during admission into the interior 46 of the load lock 14, for example, using the purge/vent fluid inlet MFC 114 (shown in FIG. 2). As will be appreciated by those of skill in the art of the present disclosure, throttling flow of the heated purge/vent fluid 148 limits (or eliminates) throughput reduction than may otherwise be associated with the removal of the surface moisture 48. In accordance with certain examples, flow of the heated purge/vent fluid 148 and evaporated moisture 132 through the purge/vent fluid outlet conduit 110 may also be throttled, for example, using the purge/vent fluid outlet MFC 116 (shown in FIG. 2). As will also be appreciated by those of skill in the art in view of the present disclosure, throttling flow of the heated purge/vent fluid 148 and evaporated moisture 132 through the purge/vent fluid outlet conduit 110 may increase the rate at which the surface moisture 48 is evaporated, allowing the moisture removal process to be performed during which the load lock 14 is idle. As will also be appreciated by those of skill in the art in view of the present disclosure, mass flow of both the heated purge/vent fluid 148 and mass flow of the heated purge/vent fluid 148 and evaporated moisture 132 may be throttled, limiting constraints to the scheduling of substrate transfers into and out of the load lock 14 around moisture removal from the load lock 14.

Referring to FIG. 4, removal of the heated purge/vent fluid 148 and the evaporated moisture 132 may be accomplished, at least in part, by opening the front-end gate valve 42. As will be appreciated by those of skill in the art in view of the present disclosure, removal of the heated purge/vent fluid 148 evaporated moisture 132 through the front-end gate valve 42 allows for rapid moisture removal. In this respect, in examples where open area of the front-end gate valve 42 is relatively large in comparison of flow area within purge/vent fluid outlet conduit 110, opening the front-end gate valve 42 allows at least a portion of the evaporated moisture 132 to be removed through the front-end enclosure 22 (shown in FIG. 1), exploiting the dilutive effect that the relatively large volume of the front-end enclosure 22 in relation to the load lock 14. As will also be appreciated by those of skill in the art in the art in view of the present disclosure, removal of the evaporated moisture through the front-end gate valve 42 also limits throughput loss associated with moisture removal within the load lock 14, for example, by scheduling removal of the surface moisture 48 in coordination with the transfer of the substrate 2 into the load lock 14 (shown with an arrow in FIG. 4).

Referring to FIG. 5, the substrate moisture 50 may be removed from within the interior 46 of the load lock 14 by (a) transferring the substrate 2 carrying the substrate moisture 50 into the load lock 14, (b) fluidly separating the interior 46 of the load lock 14 from the front-end module 12 (shown in FIG. 1) and the back-end module 16 (shown in FIG. 1), (c) heating the purge/vent fluid 122 (shown in FIG. 2), and (d) providing heated purge/vent fluid 148 to the interior 46 of the load lock 14. Therein (e) the heated purge/vent fluid 148 evaporates the substrate moisture 50, and (f) the heated purge/vent fluid 148 and evaporated moisture 132 is thereafter removed from the load lock 14. As above, it is contemplated that fluid separation of the interior 46 of the load lock 14 from the front-end module 12 and the back-end module 16 be accomplished by closing the front-end gate valve 42 and the back-end gate valve 44, respectively; heating of the purge/vent fluid 122 be accomplished outside of the load lock 14 as the purge/vent fluid 122 transverses the heater element 106; and provision of the heated purge/vent fluid 148 is accomplished opening the purge/vent fluid inlet valve 108. Evaporation of the substrate moisture 50 is accomplished by directly heating the substrate moisture 50 using the heated purge/vent fluid 148 (e.g., indirectly using the electric cartridge heater and/or external heater). Removal of the heated purge/vent fluid 148 and the evaporated moisture 132 is accomplished by opening the purge/vent fluid outlet valve 112 and flowing the heated purge/vent fluid 148 and the evaporated moisture 132 to external environment 26 (shown in FIG. 1).

In certain examples, flow of the heated purge/vent fluid 148 may be throttled during admission into the interior 46 of the load lock 14, for example, using the purge/vent fluid inlet MFC 114 (shown in FIG. 2). As will be appreciated by those of skill in the art of the present disclosure, throttling flow of the heated purge/vent fluid 148 limits (or eliminates) throughput reduction than may otherwise be associated with the removal of the substrate moisture 50. In accordance with certain examples, flow of the heated purge/vent fluid 148 and the evaporated moisture 132 through the purge/vent fluid outlet conduit 110 may also be throttled, for example, using the purge/vent fluid outlet MFC 116 (shown in FIG. 2). As will also be appreciated by those of skill in the art in view of the present disclosure, throttling flow of the heated purge/vent fluid 148 and the evaporated moisture 132 through the purge/vent fluid outlet conduit 110 may also increase the rate at which the substrate moisture 50 is evaporated. As will also be appreciated mass flow of both the heated purge/vent fluid 148 through the purge/vent fluid inlet conduit 104 and mass flow of the heated purge/vent fluid 148 and the evaporated moisture 132 through the purge/vent fluid outlet conduit 110 may be throttled to accommodate scheduling of substrate transfers into and out of the load lock 14.

As shown in FIG. 6, removal of the heated purge/vent fluid 148 and the evaporated moisture 132 may also be accomplished by opening the back-end gate valve 44, for example, during transfer of the substrate 2 from the load lock 14 to the back-end module 16 (shown in FIG. 1). As will be appreciated by those of skill in the art in view of the present disclosure, this can increase that rate at which the heated purge/vent fluid 148 and evaporated moisture 132 is removed from the interior 46 of the load lock 14 in examples where open area the back-end gate valve 44 is relatively large in relation to flow area of the purge/vent fluid outlet conduit 110. As will be appreciated by those of skill in the art, the relatively large volume of the back-end chamber 28 in comparison to volume of the load lock housing 38 may provide a dilatative effect, accelerating rate of removal of the evaporated moisture 132 from within the interior 46 of the load lock 14 in certain examples.

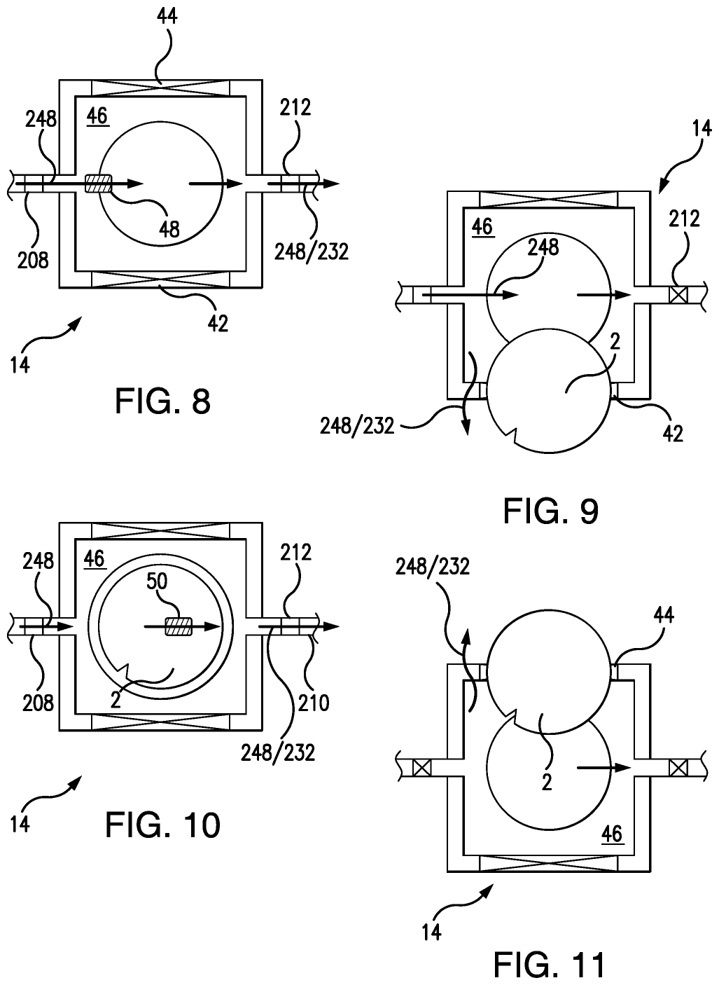

With reference to FIG. 7, the load lock 14 and a heated purge/vent fluid arrangement 200 are shown. The heated purge/vent fluid arrangement 200 is similar to the heated purge/vent fluid arrangement 100 (shown in FIG. 1) and in this respect includes a purge/vent fluid source 202, a purge/vent fluid inlet conduit 204, a heater element 206, a purge/vent fluid inlet valve 208, and a controller 220. The heated purge/vent fluid arrangement 200 additionally includes an evacuation conduit 210, an evacuation valve 212, and an evacuation pump 252. In certain examples, the heated purge/vent fluid arrangement 200 may further include a purge/vent fluid inlet mass flow controller (MFC) 214, an evacuation MFC 216, and/or a hygrometer 218. As will be appreciated by those of skill in the art in view of the present disclosure, the heated purge/vent fluid arrangement 200 may include fewer or additional elements than shown in FIG. 7 and remain within the scope of the present disclosure.

The purge/vent fluid source 202 is configured to provide a flow of a purge/vent fluid 222 to the load lock 14, which is similar to the purge/vent fluid 122 (shown in FIG. 2). The purge/vent fluid inlet conduit 204 connects the purge/vent fluid source 202 to the load lock 14 and is configured to flow the purge/vent fluid 222 to the load lock 14, and may be similar to the purge/vent fluid inlet conduit 104 (shown in FIG. 2). The heater element 206 is similar to the heater element 106 (shown in FIG. 2) and is configured to heat the purge/vent fluid 222 prior to admission to the interior 46 of the load lock 14. The purge/vent fluid inlet valve 208 is similar to the purge/vent fluid inlet valve 108 (shown in FIG. 2) and is configured to admit heated purge/vent fluid 248 to the interior 46 of the load lock 14.

The evacuation conduit 210 connects the load lock 14 to the evacuation pump 252. In this respect the evacuation conduit 210 fluidly couples the interior 46 of the load lock 14 to the evacuation valve 212 for selective evacuation of the interior 46 of the load lock 14 using the evacuation pump 252, the evacuation conduit 210 configured to flow the heated purge/vent fluid 248 and evaporated moisture 232 to the external environment 26 through the evacuation pump 252. It is contemplated that evacuation be accomplished using the evacuation valve 212, which is arranged along the evacuation conduit 210 and configured to provide selective fluid communication between the interior 46 of the load lock 14 and the evacuation pump 252. For example, it is contemplated that the evacuation valve 212 have an open position, wherein the evacuation valve 212 fluidly couples the interior 46 of the load lock 14 to the external environment 26 (shown in FIG. 1), and a closed position, wherein the evacuation valve 212 fluidly separates the interior 46 of the load lock 14 from the external environment 26. In this respect the evacuation valve 212 may be operatively associated with the controller 220, the controller 220 in turn configured to move the purge/vent the evacuation valve 212 between the closed position and the open position to provide selective fluid communication between the interior 46 of the load lock 14 and the external environment 26 for evacuation of the load lock 14.

In certain examples, the evacuation pump 252 may have a staged arrangement. In this respect the evacuation pump 252 may include a roughing pump 254, a booster pump 256, and a boosting valve arrangement 258. In such examples, the roughing pump 254 may be arranged to evacuate the interior 46 of the load lock 14 to a first pressure, the booster pump 256 may be configured to evacuate the interior 46 of the load lock 14 to a second pressure that is lower than the first pressure, and the boosting valve arrangement 258 may be configured to fluidly couple the booster pump 256 to the interior 46 of the load lock 14 upon evacuation to the first pressure, the booster pump 256 thereafter evacuating the load lock 14 to the second pressure (which may be an ultra-high vacuum pressure, e.g., less than about 100 nanopascals).

In certain examples, the purge/vent fluid inlet valve 208 may be included in the purge/vent fluid inlet MFC 214. In such examples the purge/vent fluid inlet MFC 214 may be configured to throttle mass flow of the purge/vent fluid 222 flowing through the purge/vent fluid inlet conduit 204, the purge/vent fluid inlet MFC 214 being similar to the purge/vent fluid inlet MFC 114 (shown in FIG. 2). In accordance with certain examples, the evacuation valve 212 may be included in the evacuation MFC 216. In such examples the evacuation MFC 216 may be configured to throttle mass flow of the purge/vent fluid 122 through the evacuation conduit 210, the evacuation MFC 216 being similar to the purge/vent fluid outlet MFC 116 (shown in FIG. 2) in this respect. As will be appreciated by those of skill in the art in view of the present disclosure, throttling flow of the heated purge/vent fluid 248 and the evaporated moisture 232 through the evacuation conduit 210 allows the evaporated moisture to be removed from the load lock 14 using the roughing pump 254, and not the booster pump 256. This can limit cost of the booster pump 256, for example, by allowing the semiconductor processing system 10 (shown in FIG. 1) to employ booster pumps that are intolerant of entrained moisture. Throttling may be accomplished using a dew point measurement acquired from the interior 46 of the load lock 14 using the hygrometer 218, mass flow of the heated purge/vent fluid 248 into the load lock 14 and/or mass flow of the heated purge/vent fluid 248 and the evaporated moisture 232 increased or decreased based on the acquired dew point measurement.

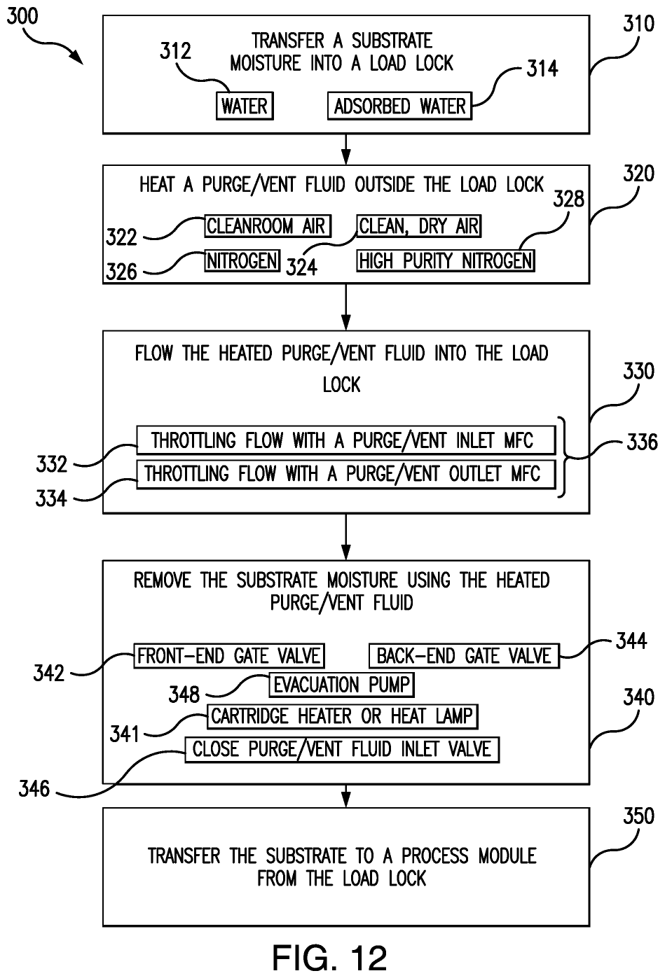

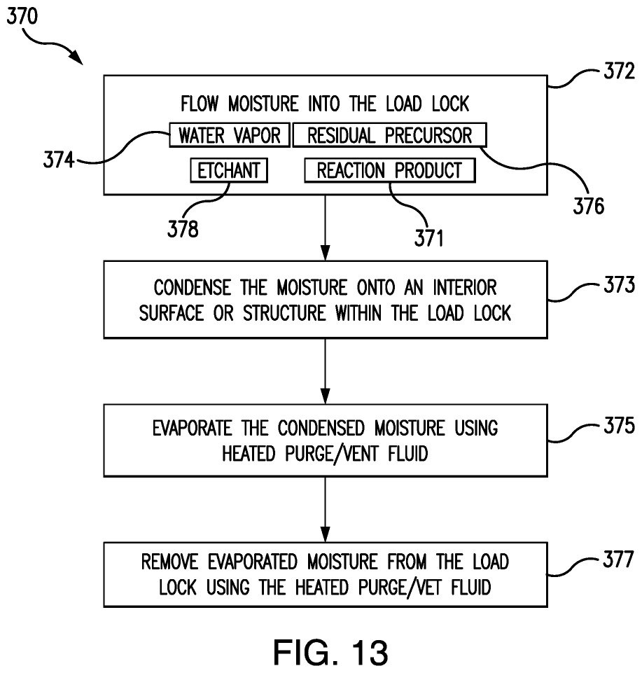

With reference to FIGS. 8-11, moisture removal from within the load lock 14 during substrate transfer between the front-end module 12 (shown in FIG. 1) and the back-end module 16 (shown in FIG. 1) in an example of the semiconductor processing system 10 (shown in FIG. 1) where an evacuated atmosphere is maintained within the back-end chamber 28 (shown in FIG. 1). As shown in FIGS. 8 and 9, the surface moisture 48 may be removed prior to transfer of substrates into the load lock 14. As shown in FIGS. 10 and 11, the substrate moisture 50 may be removed prior to transfer substrates from the load lock 14 to the back-end module 16. As in the prior example, as will be appreciated by those of skill in the art in view of the present disclosure, removing the surface moisture 48 and the substrate moisture 50 limits (or eliminates) risk that the surface moisture 48 and/or the substrate moisture 50 may cause corrosion with the semiconductor processing system 10 and/or influence properties of the material layer 4 (shown in FIG. 1) deposited onto the substrate 2. It is also the understood and appreciated that the heated purge/vent fluid arrangement 200 may also (or alternatively) be employed to remove moisture during transfer of substrates into the load lock 14 from the back-end module 16 as well as from the load lock 14 into the front-end module 12 and remain within the scope of the present disclosure.

Referring to FIG. 8, the surface moisture 48 may be removed from within the interior 46 of the load lock 14 by (a) fluidly separating the interior 46 of the load lock 14 from both the front-end module 12 (shown in FIG. 1) and the back-end module 16 (shown in FIG. 1), (b) heating the purge/vent fluid 222 (shown in FIG. 7), and (c) providing heated purge/vent fluid 248 to the interior 46 of the load lock 14. Therein (d) the heated purge/vent fluid 248 evaporates the surface moisture 48, and the (e) the heated purge/vent fluid 248 and evaporated moisture 232 are thereafter removed from the load lock 14. Fluid separation of the interior 46 of the load lock 14 from the front-end module 12 and the back-end module 16 may be accomplished by closing the front-end gate valve 42 and the back-end gate valve 44, respectively. Heating of the purge/vent fluid 222 may be accomplished outside of the load lock 14 (e.g., in the purge/vent fluid inlet conduit 104) using the heater element 206 (shown in FIG. 7). Provision of the heated purge/vent fluid 248 to the interior 46 of the load lock 14 may be accomplished by moving the purge/vent fluid inlet valve 208 to the open position. Evaporation of the surface moisture 48 may be accomplished by directly heating the surface moisture 48 using the heated purge/vent fluid 248, which may also be accomplished independently (or in conjunction with) heating with the electric cartridge heater and/or external heat lamp, reducing time required to evaporated the surface moisture 48. Removal of the heated purge/vent fluid 248 and evaporated moisture 232 may be accomplished by moving the evacuation valve 212 to the open position.

In certain examples, flow of the heated purge/vent fluid 248 may be throttled during admission into the interior 46 of the load lock 14, for example, using the purge/vent fluid inlet MFC 214 (shown in FIG. 7). As will be appreciated by those of skill in the art of the present disclosure, throttling flow of the heated purge/vent fluid 248 may limit (or eliminate) throughput reduction otherwise associated with the removal of the surface moisture 48. In accordance with certain examples, flow of the heated purge/vent fluid 248 and evaporated moisture 232 through the evacuation conduit 210 may also be throttled, for example, using the evacuation MFC 216 (shown in FIG. 7). As will also be appreciated by those of skill in the art in view of the present disclosure, throttling flow of the heated purge/vent fluid 248 and evaporated moisture 232 through the purge/vent fluid outlet conduit 110 may increase the amount of the surface moisture 48 evacuated using the roughing pump 254 only, and not the booster pump 256, limiting cost of the booster pump 256.

As shown in FIG. 9, removal of the heated purge/vent fluid 248 and evaporated moisture 232 through the purge/vent fluid outlet conduit 110 may also be accomplished by opening the front-end gate valve 42, for example, during transfer of the substrate 2 into the load lock 14, which is the illustrated example is accomplished in conjunction with closure of the evacuation valve 212. As will be appreciated by those of skill in the art in view of the present disclosure, removal through the front-end gate valve 42 may increase that rate at which the heated purge/vent fluid 248 and evaporated moisture 232 is removed from the interior 46 of the load lock 14, for example, in load locks where open area of the front-end of the front-end gate valve 42 is relatively large in relation to flow area of the evacuation conduit 210.

As shown in FIG. 10, the substrate moisture 50 may also be removed from within the interior 46 of the load lock 14 using the heated purge/vent fluid 248. As shown in FIG. 10, removal of the substrate moisture 50 may be accomplished by (a) transferring the substrate 2 carrying the substrate moisture 50 into the load lock 14, (b) fluidly separating the interior 46 of the load lock 14 from the front-end module 12 (shown in FIG. 1) and the back-end module 16 (shown in FIG. 1), (c) heating the purge/vent fluid 222 (shown in FIG. 7) outside of the load lock 14, and (d) providing heated purge/vent fluid 248 to the interior 46 of the load lock 14. Therein, (e) the heated purge/vent fluid 248 evaporates the substrate moisture 50 by directly heating the surface moisture 48, (f) the heated purge/vent fluid 148 and evaporated moisture 132 thereafter being removed from the interior 46 of the load lock 14 by the evacuation pump 252 (shown in FIG. 7). Fluid separation of the interior 46 of the load lock 14 from the front-end module 12 and the back-end module is accomplished by closing the front-end gate valve 42 and the back-end gate valve 44, respectively. Heating of the purge/vent fluid 222 is accomplished outside of the load lock 14 (e.g., in the purge/vent fluid inlet conduit 104) using the heater element 206 (shown in FIG. 6).

Provision of the heated purge/vent fluid 248 to the load lock may be accomplished by moving the purge/vent fluid inlet valve 208 to the open position. Evaporation of the substrate moisture 50 may be accomplished by directly heating the substrate moisture 50 using the heated purge/vent fluid 248, for example, without transferring heat through the bulk material forming the walls of the load lock housing 38 using a cartridge heater and/or external heat lamp. Removal of the heated purge/vent fluid 248 and the evaporated moisture 232 may be accomplished by moving the evacuation valve 212 to the open position, and drawing the heated purge/vent fluid 248 and the evaporated moisture 232 out of the load lock using the evacuation pump 252.

In certain examples, flow of the heated purge/vent fluid 248 may be throttled during admission into the interior 46 of the load lock 14, for example, using the purge/vent fluid inlet MFC 214 (shown in FIG. 7). As will be appreciated by those of skill in the art of the present disclosure, throttling flow of the heated purge/vent fluid 248 limits the effect that venting the load lock 14 while evacuated could otherwise have on the rate of removal of the surface moisture 48. In accordance with certain examples, flow of the heated purge/vent fluid 248 and the evaporated moisture 232 through the evacuation conduit 210 may also be throttled, for example, using the evacuation MFC 216 (shown in FIG. 7). As will also be appreciated by those of skill in the art in view of the present disclosure, throttling flow of the heated purge/vent fluid 248 and the evaporated moisture 232 drawn through the evacuation conduit 210 may increase the rate at which the substrate moisture 50 is evaporated, for example, by increasing the interval during which the heated purge/vent fluid 248 is resident within the load lock 14. As will also be appreciated by those of skill in the art in view of the present disclosure, mass flow of both the heated purge/vent fluid 248 provided to the load lock 14 and mass flow of the heated purge/vent fluid 248 and evaporated moisture 232 evacuated from the load lock 14 may be throttled, for example, to increase the amount of the substrate moisture 50 removed by the roughing pump 254 and limit the amount of substrate moisture 50 removed using the booster pump 256.

As shown in FIG. 11, the heated purge/vent fluid 248 and the evaporated moisture 232 may also (or alternatively) removed by opening the back-end gate valve 44, for example, during transfer of the substrate 2 from the load lock 14 to the back-end module 16 (shown in FIG. 1). As will be appreciated by those of skill in the art in view of the present disclosure, removing the heated purge/vent fluid 248 and the evaporated moisture 232 may increase that rate at which the heated purge/vent fluid 248 and evaporated moisture 232 is removed from the interior 46 of the load lock 14, for example, in load locks where the open area the back-end gate valve 44 is relatively large in relation to flow area of the evacuation conduit 210. As will also be appreciated by those of skill in the art, the relatively large volume of the back-end chamber 28 (shown in FIG. 1) relative to that of the load lock housing 38 may limit the effect that introducing the evaporated moisture into the evacuated atmosphere maintained within the back-end chamber 28.

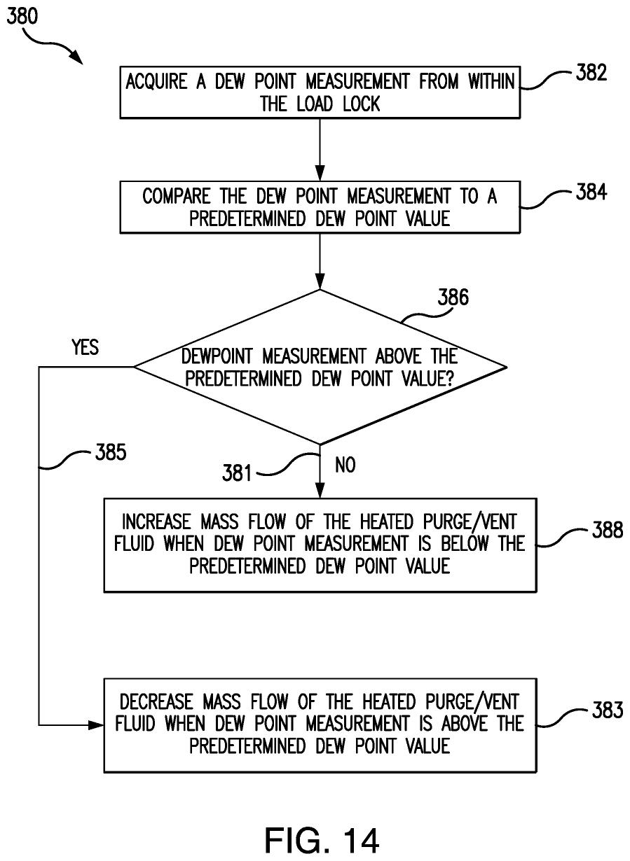

With reference to FIGS. 12-14, the moisture control method 300 is shown. As shown in FIG. 12, a substrate carrying substrate moisture is transferred into a load lock from a front-end module a semiconductor processing system, e.g., the substrate 2 (shown in FIG. 1) carrying the substrate moisture 50 transferred into the load lock 14 (shown in FIG. 1) from the front-end module 12, as shown with box 310. A purge/vent fluid is heated outside of the load lock using a heater element, e.g., the purge/vent fluid 122 (shown in FIG. 2) using the heater element 106 (shown in FIG. 2), as shown with box 320. The heated purge/vent fluid is flowed into the load lock using a purge/vent fluid inlet conduit, e.g., the heated purge/vent fluid 148 (shown in FIG. 3) using the purge/vent fluid inlet conduit 104 (shown in FIG. 2), as shown with box 330. Once admitted into the load lock it is contemplated that the heated purge/vent fluid remove the substrate moisture from the substrate using the heated purge/vent fluid, for example, by evaporating the substrate moisture while the substrate is supported within the load lock, as shown with box 340. The substrate is thereafter transferred from the load lock to a process module for processing using the process module, e.g., to the process module 18 (shown in FIG. 1) to deposit the material layer 4 (shown in FIG. 1) onto the substrate, as shown with box 350.

In certain examples, the substrate moisture may include water, such as adsorbed water, as shown with box 312. In this respect the substrate moisture may consist of adsorbed water, as shown with box 314. In further respect, the substrate moisture may consist of (or consist essentially of) water.

In certain examples, heating the purge/vent fluid may include heating cleanroom air, as shown with box 322. In accordance with certain examples, heating the purge/vent fluid may include heating CDA, as shown with box 324. In further examples, heating the purge/vent fluid may include heating nitrogen, such as HPN intermixed with cleanroom air, as shown with box 326. In certain examples, heating the purge/vent fluid may include heating HPN, such a purge/vent flow consisting in HPN (consisting essentially of HPN), as shown with box 328.

In certain examples, flowing the heated purge/vent fluid to the load lock may include throttling mass flow of the purge/vent fluid using a purge/vent fluid inlet MFC, e.g., the purge/vent fluid inlet MFC 114, as shown with box 332. In accordance with certain examples, flowing the heated purge/vent fluid to the load lock may include throttling mass flow of the purge/vent fluid and the evaporated moisture using a purge/vent fluid outlet MFC, e.g., the purge/vent fluid outlet MFC 116, as shown with box 334. It is contemplated that, in certain examples, flowing the heated purge/vent fluid to the load lock may include throttling mass flow of the purge/vent fluid using the purge/vent fluid inlet MFC and the purge/vent fluid outlet MFC, as shown with bracket 336.

In certain examples, removing the substrate moisture may include flowing the heated purge/vent fluid and evaporated moisture through a front-end gate valve, e.g., the front-end gate valve 42 (shown in FIG. 1), as shown with box 342. In accordance with certain examples, removing the substrate moisture may include flowing the heated purge/vent fluid and evaporated moisture through a back-end gate valve, e.g., the back-end gate valve 33 (shown in FIG. 1), as shown with box 344. In further examples, removing the substrate moisture may include closing a purge/vent fluid inlet valve, e.g., the purge/vent fluid inlet valve 208 (shown in FIG. 7), prior to transferring the substrate to the process module, as shown with box 346. It is contemplated that, in certain examples, removing the substrate moisture may include evacuating the heated purge/vent gas and evaporated moisture from the load lock using an evacuation pump, e.g., the evacuation pump 252 (shown in FIG. 7), as shown with box 348. In further examples, removing the substrate moisture may include heating the load lock using a cartridge heater or external heater, such as using the cartridge heater or external heat lamp. In this respect the heater element may cooperate with the cartridge heater or external heater to remove the substrate moisture from the substrate, as shown with box 341.

As shown in FIG. 13, the moisture control method 300 may include removing surface moisture, e.g., the surface moisture 48 (shown in FIG. 5), as shown with a reference arrow 370. It is contemplated that the surface moisture may be formed by flowing moisture into the load lock, as shown with box 372. For example, one or more of water vapor (shown with box 374), a residual precursor (shown with box 376), residual etchant (shown with box 378), and/or a reaction product (shown with box 371) may be flowed into the load lock. The one or more of water vapor, residual precursor, residual etchant, and/or a reaction product is condensed onto an interior surface or structure within the load lock, e.g., the chill plate/substrate rack 40 (shown in FIG. 1), as shown with box 373. The condensed one or more of residual precursor, residual etchant, and/or a reaction product is thereafter evaporated using the heated purge/vent fluid, as shown with box 375. The evaporated one or more of one or more of residual precursor, residual etchant, and/or a reaction product using the heated purge/vent fluid is thereafter removed from the load lock, as shown with box 377.

As shown in FIG. 14, the moisture control method 300 may further include controlling moisture using a measurement of dew point acquired from within the load lock, as shown with a reference arrow 380. It is contemplated that the dew point measurement be acquired, such as using a hygrometer, e.g., the hygrometer 118 (shown in FIG. 2), fluidly coupled to an interior of the load lock, as shown with box 382. The dew point measurement is compared to a predetermined dew point value, as shown with box 384 and box 386. It is contemplated that mass flow of the heated purge/vent fluid admitted to the load lock be increased when the acquired dew point measurement is greater than the predetermined dew point value, a shown with box 388 and arrow 381. It is further contemplated that mass flow of the heated purge/vent fluid admitted to the load lock be decreased when the dew point measurement is less than the predetermined dew point value, as shown with box 383 and arrow 385.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above. As will be appreciated by those of skill in the art in view of the present disclosure, evacuating the interior 46 of the load lock 14 using evacuation pump 252 allows the load lock 14 to transfer substrates, e.g., the substrate 2 (shown in FIG. 1), into semiconductor processing systems having evacuated back-end process modules, such as employed for depositing material layers prone to oxidation.

The headings provided herein, if any, are for convenience only and do not necessarily affect the scope or meaning of the devices and methods disclosed herein.

1. A moisture control method, comprising:
at a semiconductor processing system including a front-end module connected to a load lock, a process module coupled to the front-end module by the load lock, a purge/vent fluid inlet conduit connected to the load lock, a heater element coupled to the load lock by the purge/vent fluid inlet conduit, and a controller operably connected to the heater element;
transferring a substrate carrying substrate moisture from the front-end module into the load lock;
heating a purge/vent fluid using the heater element;
flowing the heated purge/vent fluid into the load lock using the purge/vent fluid inlet conduit;
removing the substrate moisture from the load lock using the heated purge/vent fluid; and
transferring the substrate from the load lock to the process module for processing using the process module.

2. The method of claim 1, wherein the heated purge/vent fluid comprises (a) cleanroom air; (b) clean, dry air; (c) nitrogen; or (d) high purity nitrogen, wherein the substrate moisture comprises water.

3. The method of claim 1, wherein the load lock comprises an electric cartridge heater seated in a wall of the load lock or an external heater, the method further comprising heating the load lock using the electric cartridge heater or the external heater.

4. The method of claim 1, further comprising a purge/vent fluid inlet valve arranged along the purge/vent fluid inlet conduit and operatively associated with the controller, the method further comprising closing the purge/vent fluid inlet valve prior to transferring the substrate to the process module.

5. The method of claim 1, wherein the semiconductor processing system further comprises a purge/vent fluid inlet mass flow controller (MFC) arranged along the purge/vent fluid inlet conduit and operatively associated with the controller, and wherein flowing the heated purge/vent fluid includes throttling mass flow of the purge/vent fluid using the purge/vent fluid inlet MFC.

6. The method of claim 1, wherein the semiconductor processing system further comprises a front-end gate valve coupling the front-end module to the load lock, and wherein removing the substrate moisture includes flowing the heated purge/vent fluid and evaporated moisture through the front-end gate valve.

7. The method of claim 1, wherein the semiconductor processing system further comprises a back-end gate valve coupling the load lock to the process module, and wherein removing the substrate moisture includes flowing the heated purge/vent fluid and evaporated moisture through the back-end gate valve.

8. The method of claim 1, further comprising removing surface moisture from an interior surface or structure within the load lock using the heated purge/vent fluid, wherein the surface moisture comprises at least one of water, a condensed precursor, and a condensed reaction product.

9. The method of claim 1, further comprising an evacuation pump fluidly coupled to the load lock, wherein the removing the substrate moisture includes evacuating the heated purge/vent gas and evaporated moisture from the load lock using the evacuation pump.

10. The method of claim 1, wherein the substrate moisture consists of adsorbed water resident on the substrate.

11. The method of claim 1, wherein the substrate is an unprocessed substrate, the method further comprising:
flowing one or more of a residual precursor, residual etchant, and a reaction product from the process module into the load lock;
condensing the one or more of the residual precursor, the residual etchant, and the reaction product within the load lock;
evaporating the condensed the one or more of the residual precursor, the residual etchant, and the reaction product using the heated purge/vent fluid; and
removing the evaporated the one or more of the residual precursor, the residual etchant, and the reaction product from the load lock using the heated purge/vent fluid.

12. The method of claim 1, wherein the semiconductor processing system further comprises a hygrometer fluidly coupled to the load lock and disposed in communication with the controller, wherein flowing the heated purge/vent fluid to the load lock comprises:
acquiring a dew point measurement from an interior of the load lock using the hygrometer;
comparing the dew point measurement to a predetermined dew point value using the controller;
increasing mass flow of the heated purge/vent fluid admitted to the load lock when the dew point measurement is greater than the predetermined dew point value; and
decreasing mass flow of the heated purge/vent fluid admitted to the load lock when the dew point measurement is less than the predetermined dew point value.

13. A semiconductor processing system, comprising:
a front-end module connected to a load lock;
a process module coupled to the front-end module by the load lock;
a purge/vent fluid inlet conduit connected to the load lock;
a heater element coupled to the load lock by the purge/vent fluid inlet conduit; and
a controller operably connected to the heater element and responsive to instructions recorded on a non-transitory machine-readable medium to:
transfer a substrate carrying substrate moisture from the front-end module into the load lock;
heat a purge/vent fluid using the heater element;
flow the heated purge/vent fluid into the load lock using the purge/vent fluid inlet conduit;
remove the substrate moisture from the load lock using the heated purge/vent fluid; and
transfer the substrate from the load lock to the process module for processing using the process module.

14. The semiconductor processing system of claim 13, further comprising a purge/vent fluid inlet valve arranged along the purge/vent fluid inlet conduit.

15. The semiconductor processing system of claim 13, further comprising a purge/vent fluid inlet mass flow controller arranged along the purge/vent fluid inlet conduit and operatively associated with the controller.

16. The semiconductor processing system of claim 13, further comprising a purge/vent fluid source fluidly coupled the purge/vent fluid inlet conduit and therethrough to an interior of the load lock.

17. The semiconductor processing system of claim 13, further comprising:
an evacuation conduit connected to the load lock;
an evacuation pump connected to the evacuation conduit and fluidly coupled therethrough to the interior of the load lock; and
an evacuation mass flow controller (MFC) arranged along the evacuation conduit and operably associated with the controller.

18. The semiconductor processing system of claim 13, further comprising a hygrometer fluidly coupled to the load lock and disposed in communication with the controller, wherein the instructions further cause the controller to:
acquire a dew point measurement from an interior of the load lock using the hygrometer;
compare the dew point measurement to a predetermined dew point value using the controller;
increase mass flow of the heated purge/vent fluid admitted to the load lock when the dew point measurement is greater than the predetermined dew point value; and
decrease mass flow of the heated purge/vent fluid admitted to the load lock when the dew point measurement is less than the predetermined dew point value.

19. The system of claim 13, further comprising:
a front-end gate valve coupling the front-end module to the load lock;
a back-end gate valve coupling the load lock to the process module;
an evacuation pump coupled to the interior of the load lock; and
wherein the instructions further cause the controller to remove evaporated moisture from the interior of the load lock through at least one of the front-end gate valve, the back-end gate valve, and the evacuation pump.

20. A heated purge/vent fluid arrangement for a semiconductor processing system, comprising:
a heater element configured to be connected to a purge/vent fluid inlet conduit and thermally coupled therethrough to a load lock of the semiconductor processing system; and
a computer program product comprising a non-transitory machine-readable medium having a plurality of program modules recorded on the medium containing instructions that, when read by a processor, cause the processor to:
transfer a substrate carrying substrate moisture from a front-end module of the semiconductor processing system into the load lock;
heat a purge/vent fluid using the heater element;
flow the heated purge/vent fluid into the load lock using the purge/vent fluid inlet conduit;
remove the substrate moisture from the load lock using the heated purge/vent fluid; and
transfer the substrate from the load lock to a process module of the semiconductor processing system for processing using the process module.
